(19) United States
(12) Patent Application Publication
(10) Pub. No.: US 2001/0007715 A1
(43) Pub. Date: Jul. 12, 2001

(54) Method of coating substrate and coated article

(76) Inventors: Takayuki Toyoshima, Osaka (JP); Toshiaki Anzaki, Osaka (JP); Katsuhisa Enjoji, Osaka (JP)

Correspondence Address: SUGHRUE, MION, ZINN, MACPEAK & SEAS, PLLC, 2100 Pennsylvania Avenue, N.W., Washington, DC, 20037, US

(21) Appl. No.: 09/753,619

(22) Filed: Jan. 4, 2001

(30) Foreign Application Priority Data
Jan. 7, 2000 (JP) P. 2000-001230
Jan. 7, 2000 (JP) P. 2000-001231

(51) Int. Cl. C23C 14/34; C23C 14/28

(52) U.S. Cl. 428/426; 204/192.26

(57) ABSTRACT

A substrate is set on the periphery of a cylindrical substrate holder rotatable on its axis, and two or more sputtering cathodes having the respective targets attached thereto are set with the surfaces of their targets being parallel to the periphery of the cylindrical substrate holder and the sputtering cathodes being apart from each other. The targets are sputtered while revolving the substrate in front of the targets at least twice to form a coating comprising the materials of the target on the substrate. The targets are of materials different in refractive index, and the voltage applied to each cathode during sputtering is varied to make a substantially continuous change in composition of the coating in the thickness direction.

### FIELD OF THE INVENTION

This invention relates to a method of coating a substrate to form a coating by sputtering and a coated article obtained thereby. More particularly, it relates to a method of coating a substrate with a coating having a composition gradient in its thickness direction and a coated article obtained by the method.

### BACKGROUND OF THE INVENTION

Vacuum film formation techniques, such as vacuum evaporation and sputtering, have conventionally been adopted to form an optical coating, particularly an antireflection coating, on a substrate to provide the substrate with an optical function, particularly an antireflection function. Since precise film thickness control is demanded for obtaining a higher antireflection function, vacuum film formation techniques have been preferred to chemical film formation techniques, such as a sol-gel process, for their excellent controllability on film thickness. An antireflection coating usually has a multilayer laminate structure comprising alternating high-refractive layers and low-refractive layers.

Where a highly antireflective coating having such a multilayer structure comprising alternating high-refractive layers and low-refractive layers is formed by vacuum film formation techniques, a large-sized film formation system is required to build up a plurality of coating films different in composition, which incurs an increased cost. In addition, formation of a multilayer structure on a substrate involves the time for switching the target materials, which invites an increase in tact time.

### SUMMARY OF THE INVENTION

Accordingly, one object of the present invention is to provide a method of coating a substrate with a highly functional coating (a low reflection coating) without requiring a large-sized film formation system. The object is to provide a method of coating a substrate with a monolayer coating capable of reducing the surface reflectance of the substrate over a wide range of wavelength.

According to a first embodiment of the present invention, there is provided a method of coating a substrate which comprises setting the substrate on the periphery of a cylindrical substrate holder rotatable on its axis, setting two or more sputtering cathodes having the respective targets attached thereto with the surfaces of the targets being parallel to the periphery of the cylindrical substrate holder and the sputtering cathodes being apart from each other, sputtering the targets while rotating the cylindrical substrate holder to have the substrate pass in front of the targets at least twice to form a coating comprising the materials of the targets, wherein the targets have at least two different kinds of compositions, and the sputtering is carried out so as to make a substantially continuous change in composition of the coating in the thickness direction.

According to the coating method of the first embodiment of the present invention, the resulting coating has a composition gradient in its thickness direction. For example, the method can be applied advantageously to formation of a coating having an adhesive composition in the part in contact with the substrate and a wear-resistant composition in the surface thereof. The method can also be applied to formation of an antireflection coating whose composition gradient is such that the refractive index varies in its thickness direction to thereby reduce the surface reflectance of the substrate. That is, the method provides a substrate with a monolayer antireflection coating which reduces the reflectance of the substrate over a broad range of wavelength.

In a preferred embodiment of the coating method of the first embodiment, such a composition gradient in the coating thickness direction can be obtained by varying the power applied to each cathode during sputtering.

By this manipulation, the coating film can easily be given a composition gradient. Where the power is applied to each cathode through a previously programmed control mechanism, a coating with a composition gradient can be formed automatically with good reproducibility. In the present invention, the coating thickness deposited while the substrate passes in front of one cathode is decided by the power applied to the cathode and the number of rotations of the substrate holder.

The substrate to be coated is set around a rotatable cylindrical substrate holder, and it is coated while it is moving in front of the targets. It is preferred that the coating thickness deposited for every pass of the substrate in front of each target be 2 nm or smaller.

If the coating thickness per pass exceeds 2 nm, the coating will have a distinct layered structure, which would lessen the effect of reducing the surface reflectance of the substrate even with a composition gradient from the substrate side toward the coating surface. The preference to 2 nm or less as a coating thickness per pass is based on this reason. It is rather preferred for the coating to have vague boundaries among different compositions wherein a low-refractive material and a high-refractive material are mixed up than to have a clear layered structure.

It is preferred that the coating thickness deposited per pass in front of a target be 0.2 nm or greater. To make that thickness smaller than 0.2 nm would incur an increase of coating time, which is economically disadvantageous. If the economical disadvantage is compensated for by increasing the rotational speed of the substrate holder, damage to the rotation mechanism of the holder can result.

The power applied to each cathode can be varied according to the reflectance or the transmittance of the substrate while being coated. By this manipulation, the composition gradient in the coating thickness direction can be obtained accurately with satisfactory reproducibility.

According to the first embodiment of the present invention there is also provided an article with a coating having a composition gradient in its thickness direction obtained by the above coating method. Such an article includes, for example, a substrate with a coating exhibiting good adhesion to the substrate and excellent wear resistance, in which the coating is rich in an adhesion-improving component in the substrate side while being rich in a wear-resistant component in the surface thereof.

The above article preferably comprises a transparent glass substrate and a coating having such a composition gradient that the refractive index decreases from the substrate side to the surface thereof.

In the first embodiment of the present invention, three or more cathodes can be used. In this case, the targets attached to two cathodes out of three may have the same composition, and the target of the remaining cathode has a different composition from the other two. The two kinds of the target materials are sputtered simultaneously while controlling the power applied to each cathode to provide the coating with a refractive index gradient based on the composition gradient.

According to a second embodiment of the present invention, there is provided a method of coating a substrate to form a coating having a composition gradient in the thickness direction which comprises setting two or more sputtering cathodes having the respective targets attached thereto near to each other in a vacuum chamber having a controlled vacuum atmosphere, co-sputtering the targets simultaneously to form a coating comprising the materials of said targets, wherein at least one of the targets is different from the other target(s), and the power applied to each cathode is varied during the sputtering.

According to the coating method of the second embodiment, the part of the coating which is in contact with the substrate and the surface of the coating can be made different in composition. There being no need to build up layers of different compositions, such a large-sized apparatus for vacuum film formation as has been used for making a multilayer coating is no more required. That is, a small-sized vacuum film formation apparatus can be chosen according to the size of a substrate, resulting in reduction of cost of equipment.

The coating method of the second embodiment makes it possible to change the composition of a coating in its thickness direction to control the optical characteristics, such as a reflective index, of the coating, thereby to form an antireflection coating having a monolayer structure by controlling the change in composition. Specifically, the power applied to sputtering cathodes is varied to coat a substrate with a monolayer coating film whose refractive index in the thickness direction decreases from the substrate side toward the surface to thereby reduce the reflectance of the substrate.

In a preferred embodiment of the coating method of the second embodiment, the power applied to each cathode is varied based on the reflectance or transmittance measurements of the substrate while it is being coated. This preferred embodiment realizes the contemplated composition gradient precisely and with good reproducibility.

According to the second embodiment of the present invention there is also provided an article comprising a substrate and the monolayer antireflection coating obtained by the above coating method.

### BRIEF DESCRIPTION OF THE DRAWINGS

FIG. 1 is a cross section of an article according to the first embodiment and the refractive index distribution of the article in the thickness direction.

FIG. 2 is a schematic plan view of the sputtering apparatus used in carrying out the first embodiment.

FIG. 3 is a cross section of FIG. 2 taken along A-A line.

FIG. 4 is a cross section of FIG. 2 taken along B-B line.

FIG. 5 is a cross section of a coated article according to the second embodiment.

FIG. 6 illustrates the disposition of cathodes in a sputtering apparatus used in carrying out the second embodiment.

FIG. 7 is a schematic plan view of one of the sputtering apparatus which can be used to carry out the second embodiment.

### DETAILED DESCRIPTION OF THE INVENTION

The present invention is described in detail below by referring to the accompanying drawings.

First Embodiment:

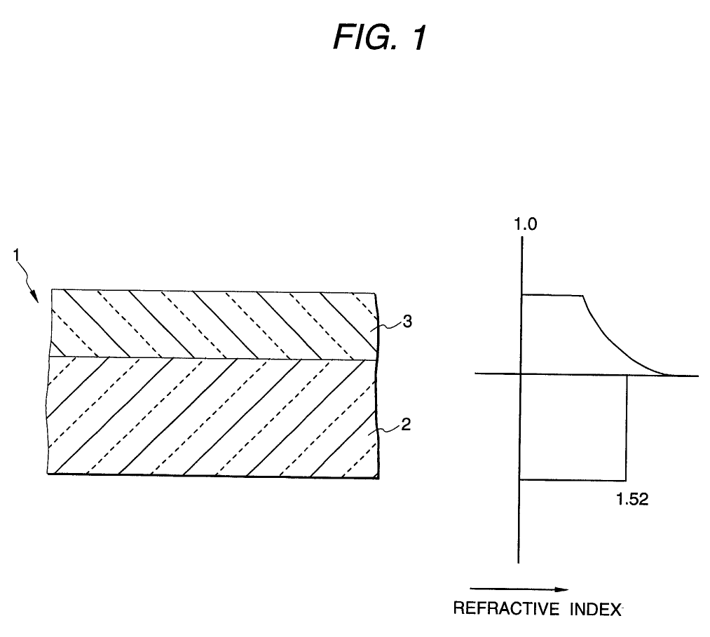

The article comprising a glass plate with an antireflection coating having the refractive index continuously varied in its thickness direction will be described in detail. FIG. 1 is a cross section of a coated article according to the invention. The article 1 shown in FIG. 1 comprises a glass plate 2 and a antireflection coating 3 having a refractive index gradient in its thickness direction. The coating 3 consists substantially of titanium dioxide (TiO₂) in the interface with the glass plate 2 and silicon dioxide (SiO₂) in the surface thereof. The composition of the coating varies in the thickness direction so as to have a decreasing refractive index from the substrate side to the surface side. It is preferred that the refractive index of the part in the substrate side be greater than that of the glass substrate, while the refractive index of the surface of the coating be smaller than that of the glass substrate.

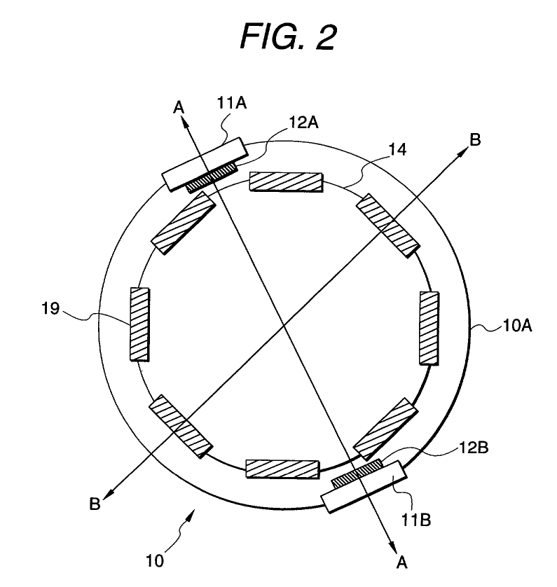

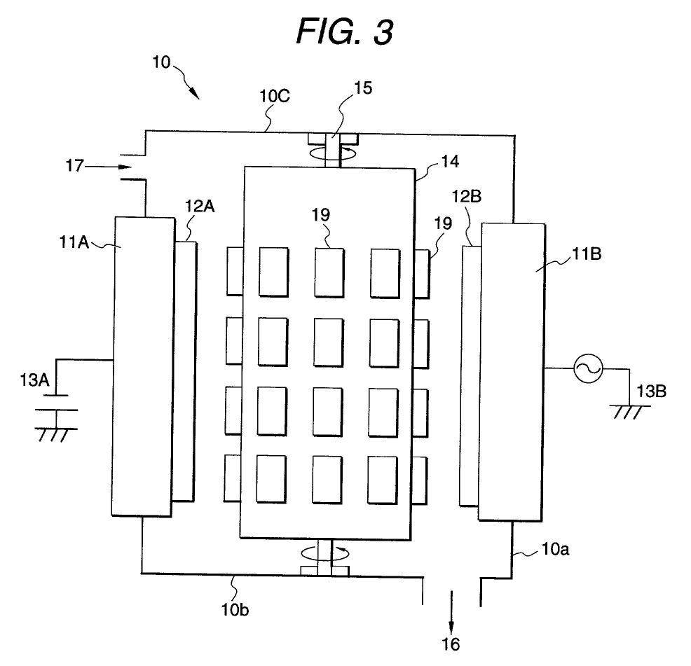

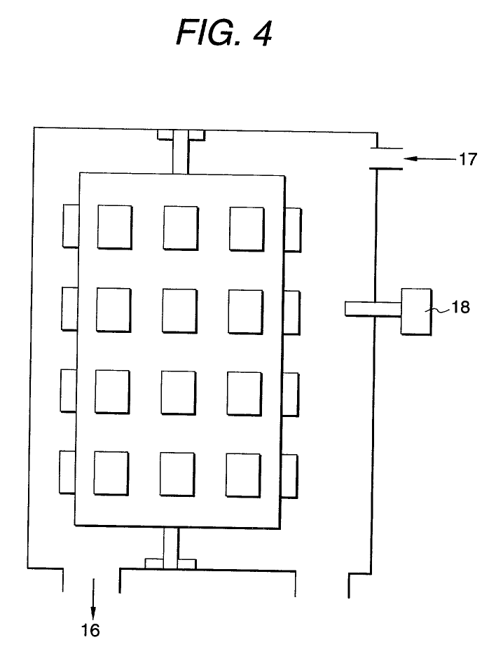

FIG. 2 is a schematic plan view of an example of the sputtering apparatus which can be used to carry out the present invention. FIGS. 3 and 4 are cross sections along AA-line and BB-line of FIG. 2, respectively. The carrousel type sputtering apparatus 10 has a closed cylindrical form made of a cylindrical wall 10a, a base 10b, and a top 10c. The closed cylinder has a vacuum port 16 while is led to a vacuum pump (not shown) and a sputtering gas inlet 17 which is led to a gas feed mechanism (not shown). The inside of the cylinder 10 is kept in a controlled vacuum atmosphere by means of the vacuum pump and the gas feed mechanism.

A plurality of substrates 19 are set around a substrate holder 14 which is rotatable on its axis 15. Cathodes 11A and 11B are set on the inner side of the cylindrical wall 10a, and targets 12A and 12B which is different from the target 12A are attached to the cathodes 11A and 11B, respectively. A voltage is applied from a power source 13A and 13B to the cathodes 11A and 11B, respectively, to sputter the targets 12A and 12B simultaneously in a sputtering atmosphere containing argon to thereby deposit the materials of the targets 12A and 12B on the revolving substrates 19 on the rotating holder 14.

The target 12A is, for example, metallic titanium for forming a high-refractive film (TiO₂ film), and the target 12B is, for example, quartz glass for forming a low-refractive film (SiO₂ film)

The power applied to the cathodes can be varied as follows to make a coating composition gradient. Where metallic titanium is attached to the cathode 11A, and quartz glass to the cathode 11B, a titanium dioxide to silicon dioxide ratio in the coating can be made 2:1, for instance, by controlling the applied power so that the oxygen-reactive sputtering rate of metallic titanium may be double the silicon dioxide sputtering rate. The composition of the coating can thus be varied in the thickness direction by changing the power applied to each cathode during sputtering. The sputtering of the targets can be carried out by DC magnetron sputtering, RF magnetron sputtering, and the like.

The control for continuously changing the power applied to each cathode during film formation is conveniently effected by means of an optical transmittance or reflectance monitor 18 as shown in FIG. 4. The transmittance or reflectance monitor 18 is set to face any one of the substrates to measure the transmittance or reflectance of the coating while being formed, and the data are processed in a calculator and sent to a feedback control system to control the power to be applied. Through this feedback control system, the coating rate can be adjusted to a predetermined one, thereby suppressing the fluctuation in optical characteristics of the coating.

The power applied to each cathode is preferably controlled so as to limit a deposit thickness per pass of each substrate in front of the two targets to 2 nm or smaller. If the deposit thickness per pass exceeds 2 nm, the boundaries among different compositions become clear to make each layer made of a single component recognizable as an optically independent layer. The deposit thickness per pass can be limited to 2 nm or smaller by reducing the power applied to the target or by increasing the rotational speed of the substrate holder.

Second Embodiment:

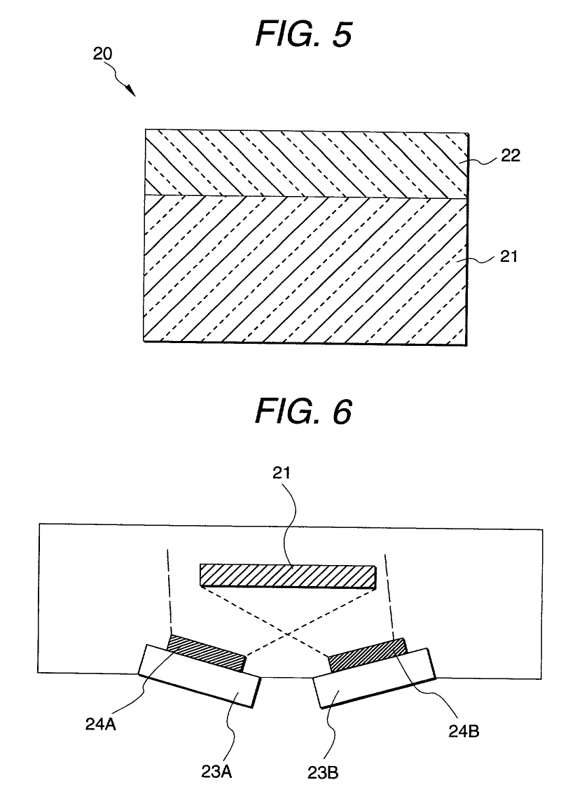

FIG. 5 is a cross section of an article according to the second embodiment. The article 20 shown in FIG. 5 comprises a glass plate 21 and a monolayer antireflection coating 22 having a composition gradient such that the refractive index decreases from the substrate side to its surface.

For example, the coating 22 can be rich in titanium dioxide in the vicinity of the interface with the glass plate 21 and rich in silicon dioxide in the vicinity of the surface thereof, and the titanium dioxide content continuously decreases in the direction from the substrate side toward the surface of the coating, while the silicon dioxide content continuously increases toward the surface, thereby making a refractive index gradient in the film thickness direction. In order to obtain an enhanced antireflection function, it is desirable that the refractive index of the part of the coating in contact with the glass substrate be greater than that of the glass substrate, and the refractive index of the surface of the coating be smaller than that of the glass substrate.

FIG. 6 illustrates the disposition of cathodes in a sputtering apparatus used in carrying out the second embodiment of the present invention. Cathodes 23A and 23B are disposed near to each other with a slight tilt to face each other, and a target 24A, for example, metallic titanium, and a target 24B, for example, quartz glass, are attached thereto, respectively. The targets are co-sputtered, mixed with a sputtering gas, typically argon, or, if necessary, a reactive sputtering gas, e.g., a mixed gas of argon and oxygen or nitrogen, and deposited on a substrate 21 simultaneously. During the sputtering, the power applied to the cathodes 23A and 23B is changed to change the sputtering rate (coating rate).

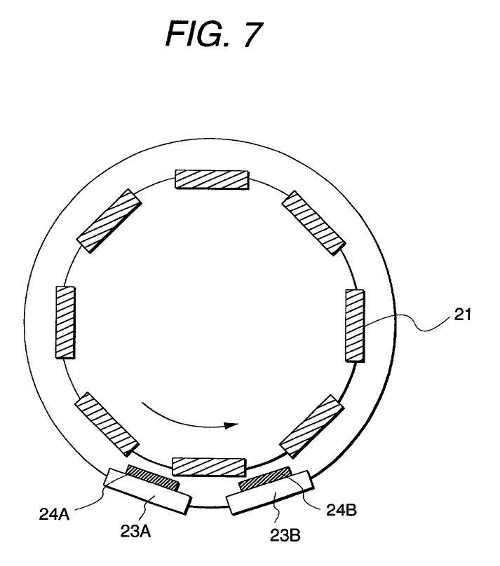

FIG. 7 is a schematic cross section of one of the sputtering apparatus used to carry out the second embodiment which is of carrousel type. Targets 24A and 24B are co-sputtered to form a coating on substrates 21 attached to a rotating carrousel wheel.

In order to obtain a highly functional optical coating, an elaborate optical design and precise composition control are desirable. For this purpose, the control for continuously changing the power applied to each cathode during film formation is conveniently effected by means of an optical transmittance monitor or an optical reflectance monitor. That is, the reflectance or transmittance of the coating while being formed is measured, and the sputtering rate is controlled by a feedback control system connected to a calculator, thereby to suppress fluctuations of optical characteristics due to slight variations of the coating rate among batches.

The present invention will now be illustrated in greater detail with reference to Examples. In every Example, a transparent glass plate was used as a substrate. The transparent glass substrate had a refractive index of 1.52, a transmittance of about 92%, and a surface reflectance of about 4%.

### EXAMPLE 1

The carrousel type sputtering apparatus shown in FIG. 2 was used. Metallic titanium and quartz glass were attached to the cathodes 11A and 11B as the targets 12A and 12B, respectively, and these targets were sputtered simultaneously. A mixed gas of argon and oxygen was used as a sputtering gas. The sputtering of metallic titanium was DC reactive sputtering, while the sputtering of quartz glass was RF sputtering. The substrates were given 10 revolutions per minute so as to form a coating to a deposit thickness of 0.5 nm per pass in front of each target. During the sputtering, the power applied to each cathode was controlled so that the coating comprised titanium dioxide in the substrate side and silicon dioxide in the surface side with its composition changing continuously therebetween. That is, the coating composition was represented by formula: xSiO₂—(1−x)TiO₂ wherein x varied from 0 to 1.

The resulting coated glass plate was found to have a surface reflectance of 0.2% at a wavelength of 550 nm, which is about one-twentieth of the glass plate's (4%), providing confirmation that the surface reflectance was markedly reduced by the coating. Virtually the same reflectance was obtained at wavelengths of 450 nm and 650 nm, which verifies that the antireflection function was effective over a broad range of wavelength.

### EXAMPLE 2

The substrates were coated by sputtering in the same manner as in Example 1, except for replacing the metallic titanium with silicon nitride (SiN) as the target 12A and the power applied to each cathode was controlled so as to form a coating having a composition gradient represented by formula: SiOₓN_{y} wherein x varied from 0 (in the part in contact with the substrate) to 2 (on the surface of the coating), and y varied from 1 (in the part in contact with the substrate) to 0 (on the surface of the coating).

The resulting coated glass plate was found to have a surface reflectance of 0.3% at a wavelength of 550 nm, providing confirmation that an antireflection function had been afforded to the glass substrate. Virtually the same reflectance was obtained at wavelengths of 450 nm and 650 nm, which verifies that the antireflection coating was effective over a broad range of wavelength.

### EXAMPLE 3

The substrate was disposed in front of and in the middle of two targets in a sputtering apparatus as shown in FIG. 6. One of the targets was quartz glass, and the other was metallic titanium. The sputtering gas was a mixed gas of argon and oxygen. Co-sputtering was carried out to form a 150 nm-thick coating while varying the applied voltage so that the coating composition might change continuously in the thickness direction. The coating composition can be represented by formula: xSiO₂—(1—x)TiO₂ (0≦x≦1).

The resulting coated glass plate was found to have a surface reflectance of 0.2% at a wavelength of 550 nm, providing confirmation that a marked antireflection function had been afforded to the substrate. Virtually the same reflectance was obtained at wavelengths of 450 nm and 650 nm, which verifies that the antireflection coating is effective over a broad range of wavelength.

### EXAMPLE 4

The substrate was coated by co-sputtering in the same manner as in Example 3, except for replacing the metallic titanium with silicon nitride (SiN) as one of the targets and using argon as a sputtering gas to form a 160 nm thick coating having a composition of SiOₓN_{y} (0≦x≦2, 0≦y≦1). The coating had a composition gradient, being rich in silicon nitride in the vicinity of the substrate and in silicon dioxide in the vicinity of the coating surface.

The resulting coated glass plate was found to have a surface reflectance of 0.3% at a wavelength of 550 nm, providing confirmation that a marked antireflection function had been afforded to the glass substrate. Virtually the same reflectance was obtained at wavelengths of 450 nm and 650 nm, which verifies that the antireflection coating is effective over a broad range of wavelengths.

According to the present invention, a coating having a composition gradient in its thickness direction can be efficiently formed on a substrate by simultaneously sputtering two or more targets having different compositions while changing the coating composition in the thickness direction substantially continuously. Further, Since a large-sized sputtering system as has been used for forming a multilayer coating is no more needed, a small-sized sputtering apparatus can be chosen according to the size of a substrate, resulting in reduction of cost of equipment.

The invention can provide a substrate with a coating which has the refractive index varied in its thickness direction and therefore serves to reduce the reflectance of the substrate.

The antireflection coating obtained by the invention has a monolayer structure and is therefore free from the problem of delamination associated with a multilayer laminate structure.

The coating method of the present invention provides a coating which does not have a multilayer structure but a monolayer structure. Since a large-sized sputtering system as has been used for forming a multilayer coating is no more needed, a small-sized sputtering apparatus can be chosen according to the size of a substrate, resulting in reduction of cost of equipment.

What is claimed is:

1. A method of coating a substrate which comprises setting the substrate on the periphery of a cylindrical substrate holder rotatable on its axis, setting two or more sputtering cathodes having the respective targets attached thereto with the surfaces of said targets being parallel to the periphery of said cylindrical substrate holder and said sputtering cathodes being apart from each other, sputtering the targets while rotating said cylindrical substrate holder to have said substrate pass in front of said targets at least twice to form a coating comprising the materials of said targets on said substrate, wherein said targets have at least two different kinds of compositions, and said sputtering is carried out so as to make a substantially continuous change in composition of the coating in the thickness direction.

2. The method according to claim 1, wherein said change in composition of the coating is made by varying the power applied to each cathode during the sputtering.

3. The method according to claim 2, wherein the coating thickness deposited for every pass of the substrate in front of each target is 2 nm or smaller.

4. The method according to claim 3, wherein the coating thickness deposited for every pass of the substrate in front of each target is 0.2 nm or greater.

5. The method according to claim 2, wherein the power applied to each cathode is varied according to the reflectance or the transmittance of the substrate while being coated.

6. An article comprising a substrate and a coating having a composition gradient in the thickness direction thereof which is obtained by the method of claim 1.

7. The article according to claim 6, wherein said substrate is transparent glass, and said coating has such a composition gradient as to have the refractive index decreased from the substrate side toward the surface thereof.

8. A method of coating a substrate comprising setting two or more sputtering cathodes having the respective targets attached thereto near to each other in a vacuum chamber having a controlled vacuum atmosphere, co-sputtering the targets simultaneously to form a coating comprising the materials of said targets, wherein at least one of said targets is different from the other target(s), and the power applied to each cathode is varied during the sputtering to form a coating having a composition gradient in the thickness direction thereof on said substrate.

9. The method of coating a substrate according to claim 8, wherein the power applied to each cathode is varied in such a manner that the resulting coating may have the refractive index in the thickness direction decreased from the substrate side to the surface thereof.

10. The method of coating a substrate according to claim 1, wherein the power applied to each cathode is varied according to the reflectance or the transmittance of the substrate while being coated.

11. An article comprising a substrate and a monolayer antireflection coating which is obtained by the method according to claim 8.
